(19) United States
(12) Patent Application Publication
(10) Pub. No.: US 2014/0016397 A1
(43) Pub. Date: Jan. 16, 2014

(54) NONVOLATILE MEMORY DEVICE AND WRITE METHOD THEREOF

(71) Applicants: WONSEOK LEE, SUWON-SI (KR); SEONGHYUN JEON, SEOUL (KR); DONG HWI KIM, YONGIN-SI (KR)

(72) Inventors: WONSEOK LEE, SUWON-SI (KR); SEONGHYUN JEON, SEOUL (KR); DONG HWI KIM, YONGIN-SI (KR)

(21) Appl. No.: 13/939,324

(22) Filed: Jul. 11, 2013

(30) Foreign Application Priority Data
Jul. 11, 2012 (KR) 10-2012-0075592

(51) Int. Cl. G11C 13/00; G11C 7/10

(52) U.S. Cl. CPC G11C 13/0069; G11C 7/10
USPC 365/148; 365/189.14; 365/158; 365/163

(57) ABSTRACT

A nonvolatile memory device includes a memory cell array including a plurality of memory cells, and a data comparison write unit connected with the memory cell array and configured to support a comparison write operation. The nonvolatile memory device further includes control logic configured to selectively execute the comparison write operation based on a comparison between an access number of the memory cell array and a reference number.

### CROSS-REFERENCE TO RELATED APPLICATIONS

A claim for priority under 35 U.S.C. §119 is made to Korean Patent Application No. 10-2012-0075592 filed Jul. 11, 2012, in the Korean Intellectual Property Office, the entire contents of which are hereby incorporated by reference.

### BACKGROUND

The inventive concepts described herein relate to a semiconductor memory device, and more particularly, to a nonvolatile memory device and a write method thereof.

A semiconductor memory device is a memory device which is fabricated using semiconductors such as silicon (Si), germanium (Ge), gallium arsenide (GaAs), indium phosphide (InP), and the like. Semiconductor memory devices are generally classified as either volatile memory devices or nonvolatile memory devices.

The volatile memory devices are characterized by the loss of stored contents at a power-off condition. Examples of volatile memory devices include certain types of random access memory (RAM) such as a static RAM (SRAM), a dynamic RAM (DRAM), a synchronous DRAM (SDRAM), and the like. In contrast, nonvolatile memory devices are characterized by the retention of stored contents even during power-off condition. Examples of nonvolatile memory devices include a read only memory (ROM), a programmable ROM (PROM), an electrically programmable ROM (EPROM), an electrically erasable and programmable ROM (EEPROM), a flash memory device, a phase-change RAM (PRAM), a magnetic RAM (MRAM), a resistive RAM (RRAM), a ferroelectric RAM (FRAM), and the like.

### SUMMARY

Example embodiments of the inventive concept provide a nonvolatile memory device that includes a memory cell array including a plurality of memory cells, and a data comparison write unit connected with the memory cell array and configured to support a comparison write operation. The nonvolatile memory device further includes control logic configured to selectively execute the comparison write operation based on a comparison between an access number of the memory cell array and a reference number.

In example embodiments, when the access number is less than the reference number, the control logic performs the comparison write operation.

In example embodiments, during the comparison write operation, the data comparison write unit reads data stored in an addressed memory cell of write data, and compares the read data with the write data.

In example embodiments, during the comparison write operation, the write data is written in the addressed memory cell when the write data does not coincide with the read data, and the write data is not written in the addressed memory cell when the write data coincides with the read data.

In example embodiments, when the access number is equal to or more than the reference number, the control logic performs a rewrite operation and does not perform the comparison write operation.

In example embodiments, during the rewrite operation, the control logic overwrites an addressed memory cell with write data.

In example embodiments, the control logic compares a write unit of the memory cell array with an access unit of the memory cell array, reads data stored in predetermined memory cells among the plurality of memory cells when the write unit is less than the access unit, and overwrites the read data in the predetermined memory cells.

In example embodiments, the predetermined memory cells correspond to a same memory block as the write data.

In example embodiments, the nonvolatile memory device further includes an access counting unit configured to count a access number of each of a plurality of blocks of the memory cell array.

In example embodiments, the reference number differs according to the blocks of the memory cell array.

In example embodiments, the plurality of memory cells is formed of variable resistance elements.

Example embodiments of the inventive concept provide a nonvolatile memory device which includes a memory cell array including a plurality of memory blocks, each of the memory blocks including a plurality of memory cells, and a data comparison write unit connected with the memory cell array and configured to support a comparison write operation. The nonvolatile memory device further includes control logic configured to, in response to a write command and write data for a memory block among the plurality of memory blocks, selectively execute either the comparison write operation or a rewrite operation based on a comparison between an access number of the memory block and a reference number of the block.

In example embodiments, the comparison write operation is executed when the access number is less than the reference number, and the rewrite operation is executed when the access number is greater than or equal to the reference number.

In example embodiments, the access number is indicative of a number of read accesses of the memory block, and the nonvolatile memory device further includes a counter for counting the number of read accesses of each of the plurality of memory blocks.

In example embodiments, at least two of the memory blocks have a different reference number.

In example embodiments, the memory cell array includes at least one of magnetoresistive random access memory (MRAM), spin transfer torque magnetoresistive random access memory (STT-MRAM), phase change random access memory (PRAM), and resistive random access memory (RRAM)

Example embodiments of the inventive concept provide a write method of a nonvolatile memory device which includes receiving a write command and write data, checking access information of a memory block corresponding to the write data in response to the write command, and performing either one of a comparison write operation and a rewrite operation based on the access information.

In example embodiments, wherein the comparison write operation is performed when an access number of an addressed memory block of the write data is less than a reference number, and the rewrite operation is performed when the access number of the addressed memory block of the write data is equal to or more than the reference number.

In example embodiments, the comparison write operation includes reading data stored in the addressed memory block, comparing the read data with the write data, and overwriting the write data in the memory block when the read data does not coincide with the write data.

In example embodiments, the rewrite operation includes writing the write data in an addressed memory block of the write data, and resetting an access number of the addressed memory block.

### BRIEF DESCRIPTION OF THE FIGURES

The above and other objects and features will become apparent from the detailed description that follows with reference to the accompanying figures, wherein like reference numerals refer to like parts throughout the various figures unless otherwise specified.

FIG. 1 is a block diagram schematically illustrating a memory system according to an embodiment of the inventive concept.

FIG. 2 is a block diagram schematically illustrating a storage device shown in FIG. 1.

FIG. 3 is a diagram illustrating a structure of a memory cell array shown in FIG. 2.

FIG. 4 is a diagram illustrating a structure of a memory cell array shown in FIG. 2 according to another embodiment of the inventive concept.

FIG. 5 is a diagram illustrating a memory cell according to an embodiment of the inventive concept.

FIGS. 6 and 7 are diagrams illustrating magnetization directions of a variable resistance element according to stored data.

FIG. 8 is a diagram for reference in describing a write operation of an STT-MRAM.

FIGS. 9 and 10 are diagrams illustrating a variable resistance element of an STT-MRAM according to embodiments of the inventive concept.

FIG. 11 is a diagram illustrating a variable resistance element of an STT-MRAM according to still another embodiment of the inventive concept.

FIGS. 12 and 13 are diagrams illustrating variable resistance elements of an STT-MRAM according to still other embodiments of the inventive concept.

FIGS. 14 and 15 are diagrams for reference in describing a comparison write operation according to an embodiment of the inventive concept.

FIG. 16 is a flow chart illustrating a write operation according to an embodiment of the inventive concept.

FIG. 17 is a block diagram schematically illustrating a memory system according to another embodiment of the inventive concept.

FIG. 18 is a block diagram schematically illustrating a storage device shown in FIG. 17 according to an embodiment of the inventive concept.

FIG. 19 is a diagram for reference is describing an operation of a storage device shown in FIG. 18.

FIG. 20 is a block diagram schematically illustrating a storage device shown in FIG. 17 according to another embodiment of the inventive concept.

FIGS. 21 and 22 are diagrams for reference in describing an operation of a storage device shown in FIG. 20.

FIG. 23 is a block diagram schematically illustrating a memory system according to another embodiment of the inventive concept.

FIG. 24 is a block diagram schematically illustrating a memory system according to still another embodiment of the inventive concept.

FIG. 25 is a block diagram schematically illustrating a memory system according to still another embodiment of the inventive concept.

FIG. 26 is a block diagram schematically illustrating a computing system including a memory system according to an embodiment of the inventive concept.

### DETAILED DESCRIPTION

Embodiments will be described in detail with reference to the accompanying drawings. The inventive concept, however, may be embodied in various different forms, and should not be construed as being limited only to the illustrated embodiments. Rather, these embodiments are provided as examples so that this disclosure will be thorough and complete, and will fully convey the concept of the inventive concept to those skilled in the art. Accordingly, known processes, elements, and techniques are not described with respect to some of the embodiments of the inventive concept. Unless otherwise noted, like reference numerals denote like elements throughout the attached drawings and written description, and thus descriptions will not be repeated. In the drawings, the sizes and relative sizes of layers and regions may be exaggerated for clarity.

It will be understood that, although the terms “first”, “second”, “third”, etc., may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the inventive concept.

Spatially relative terms, such as “beneath”, “below”, “lower”, “under”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” or “under” other elements or features would then be oriented “above” the other elements or features. Thus, the exemplary terms “below” and “under” can encompass both an orientation of above and below. The device may be otherwise oriented (rotated 90 degrees or at other orientations) and the spatially relative descriptors used herein interpreted accordingly. In addition, it will also be understood that when a layer is referred to as being “between” two layers, it can be the only layer between the two layers, or one or more intervening layers may also be present.

The terminology used herein is for the purpose of describing particular embodiments only and is not intended to be limiting of the inventive concept. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. Also, the term “exemplary” is intended to refer to an example or illustration.

It will be understood that when an element or layer is referred to as being “on”, “connected to”, “coupled to”, or “adjacent to” another element or layer, it can be directly on, connected, coupled, or adjacent to the other element or layer, or intervening elements or layers may be present. In contrast, when an element is referred to as being “directly on,” “directly connected to”, “directly coupled to”, or “immediately adjacent to” another element or layer, there are no intervening elements or layers present.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and/or the present specification and will not be interpreted in an idealized or overly formal sense unless expressly so defined herein.

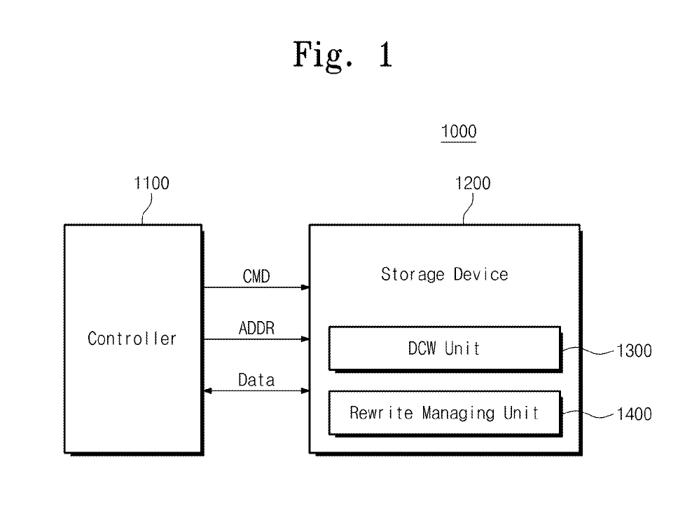

FIG. 1 is a block diagram schematically illustrating a memory system according to an embodiment of the inventive concept. Referring to FIG. 1, a memory system 1000 may include a controller 1100 and a storage device 1200, and the storage device 1200 may include a data comparison write (DWC) unit 1300 and a rewrite managing unit 1400.

The memory system 1000 may support a comparison write operation. Thus, the memory system 1000 may minimize a number of write operations and prevent deterioration of a memory cell otherwise caused by iterative write operations. The memory system 1000 may include the data comparison write unit 1300 to support the comparison write operation.

A read operation may be performed prior to execution of the comparison write operation. This may mean that data is corrupted by read disturbance not only in a case in which a conventional read operation is performed but also in a case in which a write operation is performed. To prevent data from being corrupted by the read disturbance, the memory system 1000 may include the rewrite managing unit 1400.

The controller 1100 may be electrically connected to the storage device 1200, and may provide a command CMD and an address ADDR to the storage device 1200. The controller 1100 may transmit and receive data to and from the storage device 1200. In example embodiments, the controller 1100 may be configured the same or substantially the same as a DRAM controller, and may exchange signals and data with the storage device 1200 through a DRAM interface.

For example, if a write operation is performed, the controller 1100 may provide a write command and write requested data to the storage device 1200. In this case, the controller 1100 may provide an address corresponding to the write requested data to the storage device 1200 together with the write command and the write requested data.

If a read operation is carried out, the controller 1100 may provide the storage device 1200 with a read command and an address corresponding to a read requested area. The storage device 1200 may perform the write operation or the read operation in response to a request from the controller 1100.

The data comparison write unit 1300 may perform a comparison write operation on the write requested data. Herein, the comparison write operation may mean an operation in which write data that is requested to be written (herein, “write requested data”) at a write operation is compared with data stored at a memory cell, and data is selectively written according to a comparison result.

In detail, if write requested data is different from data stored at a memory cell, the data comparison write unit 1300 may write the write requested data at the memory cell. On the other hand, if write requested data is the same as data stored at a memory cell, the data comparison write unit 1300 may not write the write requested data at the memory cell.

The rewrite managing unit 1400 may control the comparison write operation of the data comparison write unit 1300. For example, in the event that the rewrite managing unit 1400 receives a write command from the controller 1100, it may check an access number indicative of a number of times in which the controller 1100 accesses the storage device 1200. The rewrite managing unit 1400 may determine whether to perform the comparison write operation of the data comparison write unit 1300 according to the number of accesses.

For example, if an access number is less than a predetermined reference number, the rewrite managing unit 1200 may control the data comparison write unit 1300 such that the comparison write operation is performed. On the other hand, if an access number is more than a predetermined reference number, the rewrite managing unit 1200 may control the data comparison write unit 1300 such that the comparison write operation is not performed. In the case where the comparison write operation is not performed, the rewrite managing unit 1400 may control the data comparison write unit 1300 to perform a rewrite operation at which write requested data is written at a memory cell regardless of whether the write requested data is the same as data stored at the memory cell.

As described with reference to FIG. 1, the memory system 1000 may support the comparison write operation. In addition, the memory system 1000 may decide whether to perform a comparison write operation or a rewrite operation based on an access number. The memory system 1000 may prevent data from being corrupted by read disturbance by performing the rewrite operation when an access number is more than a predetermined reference number.

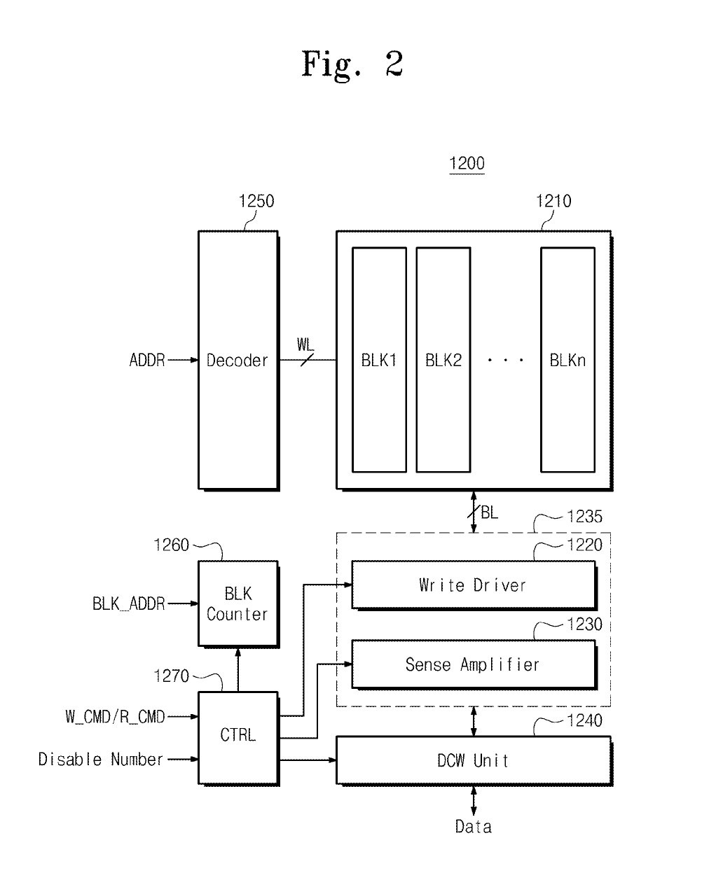

FIG. 2 is a block diagram schematically illustrating a storage device shown in FIG. 1. In FIG. 2, there is exemplarily illustrated a storage device 1200 formed of a memory chip.

Referring to FIG. 2, the storage device 1200 may include a memory cell array 1210, a write driver 1220, a sense amplifier 1230, a data comparison write unit 1240, a decoder 1250, a block counter 1260, and control logic 1270. The write driver 1220 and the sense amplifier 1230 may be referred to as a write and sense circuit 1235.

A data comparison write unit 1300 in FIG. 1 may be implemented by the data comparison write unit 1240 in shown FIG. 2, and a rewrite managing unit 1400 shown in FIG. 1 may be implemented by the block counter 1260 and the control logic 1270 shown in FIG. 2.

The memory cell array 1210 may be electrically connected with the decoder 1250 through a plurality of word lines WL. The memory cell array 1210 may be connected with the write and sense circuit 1235 through a plurality of bit lines BL. The memory cell array 1210 may include a plurality of blocks BLK1 to BLKn, each of which has a plurality of memory cells each storing data.

In example embodiments, the memory cell array 1210 may be implemented by variable resistance elements. For example, memory cells of the memory cell array 1210 may be implemented by spin-transfer torque magnetoresistive random access memory (STT-MRAM) cells.

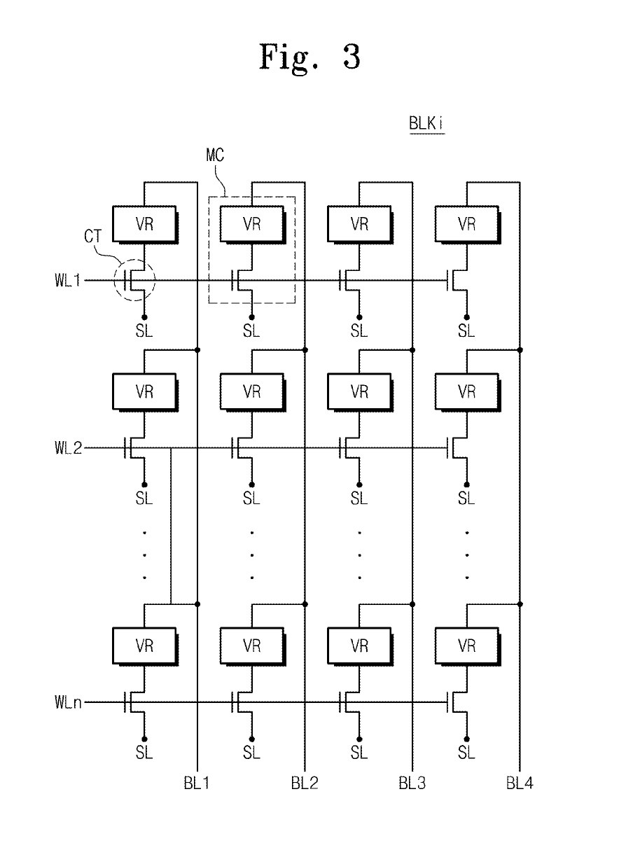

In the event that memory cells are formed of STT-MRAM cells, they may include magnetic tunnel junction elements (hereinafter, referred to as variable resistance elements) each having a magnetic material. This will be more fully described with reference to FIGS. 3 to 13.

The write driver 1220 may be connected with the memory cell array 1210 through the bit lines BL. At a write operation, the write driver 1220 may supply a write current corresponding to write requested data to the memory cell array 1210 through a bit line. At a read operation, the write driver 1220 may supply a read current through a bit line.

The sense amplifier 1230 may be connected with the memory cell array 1210. At a read operation, the sense amplifier 1230 may receive a data voltage through a bit line to amplify the received data voltage. The sense amplifier 1230 may include a plurality of sense amplifier circuits to sense and amplify data voltages, respectively. For example, each sense amplifier circuit may compare a data voltage with a reference voltage to output a digital data signal as a comparison result.

The write driver 1220 and the sense amplifier 1230 may be implemented by a module, which is referred to as the write and sense circuit 1235.

The data comparison write unit 1240 may be connected with the write and sense circuit 1235. The data comparison write unit 1240 may receive data from a controller 1100 (refer to FIG. 1). The data comparison write unit 1240 may operate responsive to a control of the control logic 1270, and may control the write and sense circuit 1235 to perform a comparison write operation or a rewrite operation.

For example, at the comparison write operation, the data comparison write unit 1240 may control the write driver 1220 and the sense amplifier 1230 to perform a read operation on a memory cell at which write requested data is to be stored. Hereinafter, such a read operation may be referred to as a pre-read operation.

If the write requested data is the same as data stored at the memory cell, the data comparison write unit 1240 may maintain the data stored at the memory cell without overwriting the memory cell. If the write requested data is not equal to data stored at the memory cell, the data comparison write unit 1240 may control the write driver 1220 such that the write requested data is overwritten at the memory cell.

At the rewrite operation, the data comparison write unit 1240 may control the write and sense circuit 1235 such that the write requested data is written at the memory cell regardless of the data stored at the memory cell. For example, at the rewrite operation, the data comparison write unit 1240 may control the sense amplifier 1230 not to perform the pre-read operation and the write driver 1220 to overwrite the write requested data at the memory cell.

The decoder 1250 may be connected with the memory cell array 1210 through the word line WL. The decoder 1250 may receive an address ADDR from the controller 1100. The decoder 1250 may decode the address ADDR to decide a memory cell to be selected by a word line and a bit line.

The block counter 1260 may receive a block address BLK_ADDR from the controller 1100. The block counter 1260 may count and manage an access number of each block BLK1˜BLKn. Herein, the access number may mean the number of read and comparison write operations executed with respect to a block. Since the comparison write operation includes a pre-read operation, the access number may mean the number of read operations and pre-read operations.

When a read operation or a pre-read operation is requested with respect to a first block BLK1, the block counter 1260 may increase a count value of the first block BLK1 by ‘1’ and manage block counting information of the first block BLK1. Likewise, when a read operation or a pre-read operation is requested with respect to a second block BLK2, the block counter 1260 may increase a count value of the second block BLK2 by ‘1’ and manage block counting information of the second block BLK2. The block counting information managed by the block counter 1260 may be stored at the memory cell array 1210 (e.g., a predetermined region of the blocks BLK1 to BLKn).

The control logic 1270 may receive a write command W_CMD or a read command R_CMD from the controller 1100. The control logic 1270 may control an overall write or read operation of the storage device 1200 in response to the write command W_CMD or the read command R_CMD.

The control logic 1270 may receive a reference number from the controller 1100. Herein, this reference number is referred to as a “disable number.” The control logic 1270 may compare the disable number with access information managed by the block counter 1260. Under the control of the control logic 1270, the comparison write operation or the rewrite operation on a write requested block may be performed according to a comparison result.

For example, if an access number on the write requested block is less than the disable number, the control logic 1270 may control an overall operation of the storage device 1200 such that the comparison write operation is performed with respect to the write requested block.

If an access number on the write requested block is more than the disable number, the control logic 1270 may control an overall operation of the storage device 1200 such that the rewrite operation is performed with respect to the write requested block.

As described in FIG. 2, the storage device 1200 may selectively perform the comparison write operation or the rewrite operation based on an access number of a write requested block. It is possible to prevent data from being corrupted by read disturbance by selectively performing either the comparison write operation or the rewrite operation.

For example, in the event that an access number exceeds a predetermined number (i.e., a disable number), data stored at an access requested block may be corrupted by read disturbance. Thus, it is possible to prevent data from being corrupted by read disturbance by performing the rewrite operation when an access number exceeds a predetermined number.

FIG. 3 is a diagram illustrating a structure of a memory cell array in FIG. 2. In FIG. 3, there is illustrated a block of a memory cell array 1210 in FIG. 2. For ease of description, it is assumed that a block BLKi in FIG. 3 is connected with four bit lines BL1 to BL4.

Referring to FIG. 3, the block BLKi may include a plurality of memory cells MC. Each memory cell MC may include a variable resistance memory VR and a cell transistor CT. A resistance value of the variable resistance element VR may vary according to current (or voltage) level and direction. Although a current (or, a voltage) is blocked, the variable resistor element VR may maintain a resistance value. That is, the variable resistor element VR may have a nonvolatile characteristic.

The variable resistor element VR may be implemented by a variety of elements. For example, the variable resistor element VR may be implemented by an

STT-MRAM element. As another example, the variable resistor element VR may be implemented by a phase change random access memory (PRAM) using a phase change material, a resistive random access memory (RRAM) using a variable resistance material of a complex metal oxide, or a magnetoresistive random access memory (MRAM) using a ferromagnetic material.

A gate of the cell transistor CT may be connected with a word line. The cell transistor CT may be switched on or off by a signal provided through the word line. A drain of the cell transistor CT may be connected to the variable resistance element VR and a source thereof may be connected to a source line SL.

For example, all sources of the cell transistors CT of the memory cells MC may be connected with the same source line. As another example, sources of the cell transistors CT of the memory cells MC may be connected with different source lines.

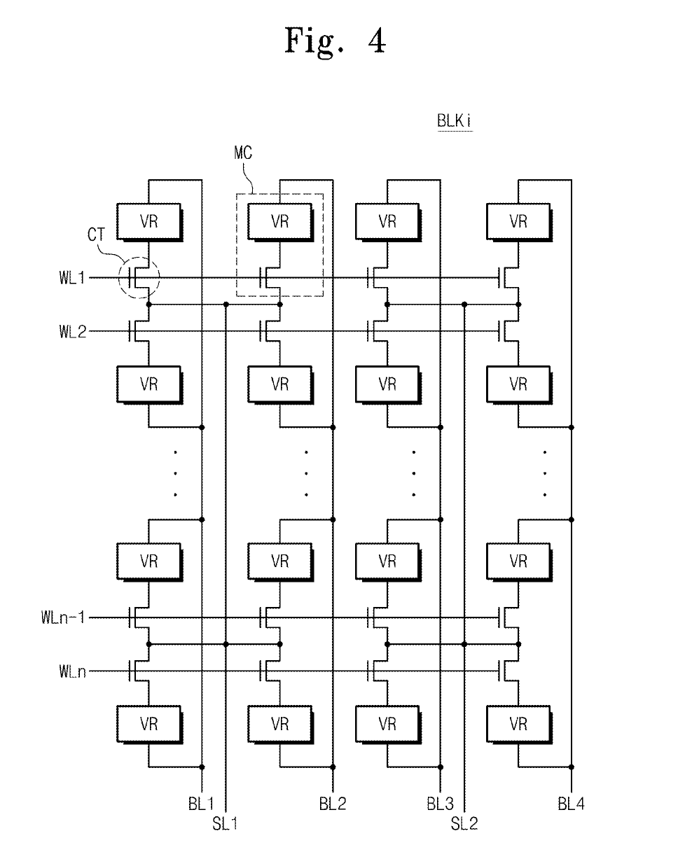

FIG. 4 is a diagram illustrating a structure of a memory cell array shown in FIG. 2 according to another embodiment of the inventive concept.

As illustrated in FIG. 4, a block BLKi of a memory cell array 1210 may be configured such that four different memory cells MC share a source line SL. A structure of the block BLKi in FIG. 4 may be similar to that in shown FIG. 3 except for the above-described difference, and a further description thereof is thus omitted.

FIG. 5 is a diagram illustrating a memory cell according to an embodiment of the inventive concept. In FIG. 5, there is illustrated an example in which a memory cell MC is implemented by an STT-MRAM cell.

The memory cell MC may include a variable resistance element VR and a cell transistor CT. A gate of the cell transistor CT may be connected with a word line (e.g., a first word line WL1). One electrode of the cell transistor CT may be connected with a bit line (e.g., a first bit line BL1) via the variable resistance element VR, and the other electrode thereof may be connected with a source line (e.g., a first source line SL1).

The variable resistance element VR may include a pinned layer 13, a free layer 11, and a tunnel layer 12 interposed between the pinned layer 13 and the free layer 11. A magnetization direction of the pinned layer 13 may be fixed, and a magnetization direction of the free layer 11 may be identical to or opposite to that of the pinned layer 13 according to a condition. An anti-ferromagnetic layer (not shown) may be further provided to fix a magnetization direction of the pinned layer 13, for example.

Data stored at the variable resistance element VR may be determined according to a resistance value measured under a bias condition in which a logic-high voltage is applied to the word line WL1 to turn on the cell transistor CT and a read current is provided in a direction from the bit line BL1 to a source line.

To execute a write operation of the STT-MRAM, a logic-high voltage may be applied to the word line WL1 to turn on the cell transistor CT, and a write current is provided between the bit line BL1 and the source line.

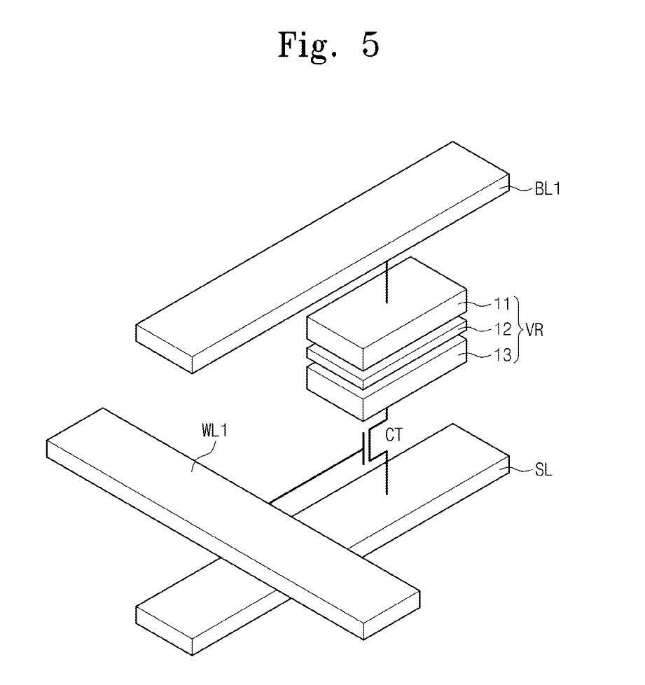

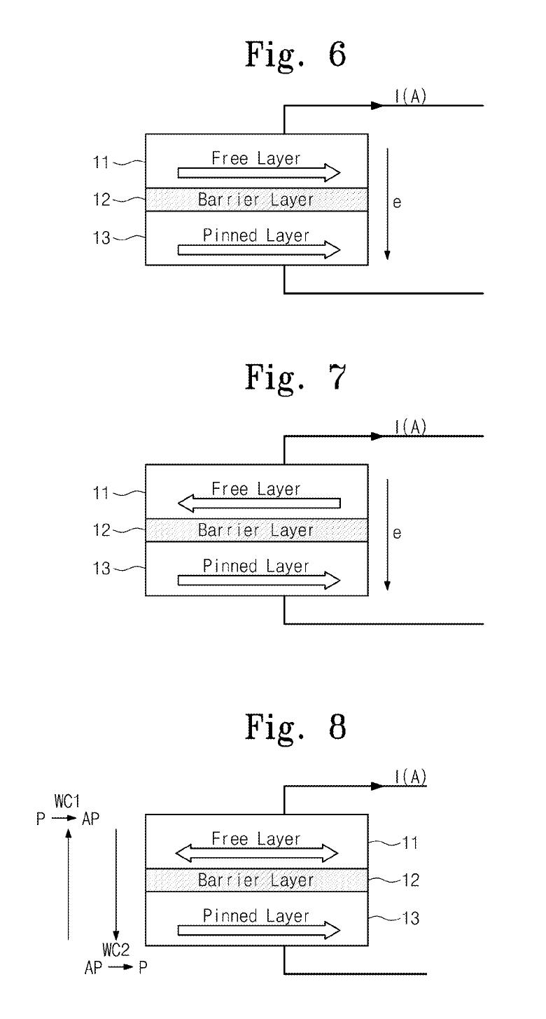

FIGS. 6 and 7 are diagrams illustrating a magnetization direction of a variable resistance element according to stored data.

A resistance value of a variable resistance element VR may vary according to a magnetization direction of a free layer 11. If a read current I is provided to the variable resistance element VR, a data voltage corresponding to a resistance value of the variable resistance element VR may be output. Since an intensity of the read current I is less than that of a write current, a magnetization direction of the free layer 11 may not be varied by the read current I.

Referring to FIG. 6, a magnetization direction of the free layer 11 may be parallel with a magnetization direction of a pinned layer 13. In this case, the variable resistance element VR may have a small resistance value indicative of data ‘0’.

Referring to FIG. 7, a magnetization direction of the free layer 11 may be anti-parallel with a magnetization direction of the pinned layer 13. In this case, the variable resistance element VR may have a large resistance value indicative of data ‘1’.

In FIGS. 6 and 7, the free layer 11 and the pinned layer 13 of an MTJ cell are illustrated to be a horizontal magnetic element. However, the inventive concept is not limited thereto. As another example, the free layer 11 and the pinned layer 13 may be implemented using a vertical magnetic element.

FIG. 8 is a diagram illustrating a write operation of an STT-MRAM.

Referring to FIG. 8, a magnetization direction of a free layer 11 may be determined according to directions of write currents WC1 and WC2. For example, if the first write current WC1 is provided, free electrons having the same spin direction as a pinned layer 13 may apply a torque to the free layer 11. In this case, the free layer 11 may be magnetized to be parallel with the pinned layer 13.

If the second write current WC2 is provided, free electrons having a spin direction opposite to that of the pinned layer 13 may apply a torque to the free layer 11. In this case, the free layer 11 may be magnetized to be anti-parallel with the pinned layer 13. That is, a magnetization direction of the free layer 11 may be changed by a spin transfer torque (STT).

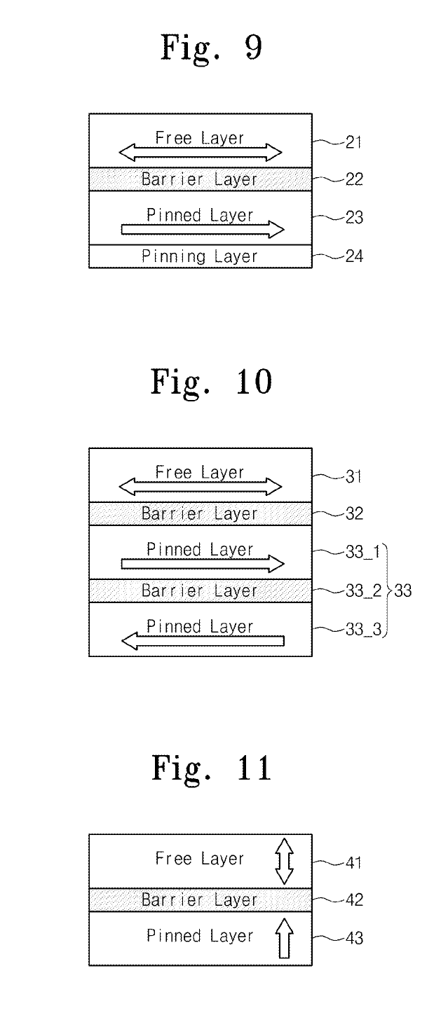

FIGS. 9 and 10 are diagrams illustrating a variable resistance element of an STT-MRAM according to embodiments of the inventive concept. In a variable resistance element in which magnetization directions are parallel with each other, a current direction may be substantially vertical to an easy axis.

Referring to FIG. 9, a variable resistance element VR may include a free layer 21, a tunnel layer 22, a pinned layer 23, and an anti-ferromagnetic layer 24.

The free layer 21 may include a material having a variable magnetization direction. A magnetization direction of the free layer 21 may be changed by an electric/magnetic factor provided from an interior and/or exterior of a memory cell.

The free layer 21 may include a ferromagnetic material including at least one of Co, Fe, or Ni. For example, the free layer 24 may include at least one selected from a group of FeB, Fe, Co, Ni, Gd, Dy, CoFe, NiFe, MnAs, MnBi, MnSb, CrO2, MnOFe2O3, FeOFe2O3, NiOFe2O3, CuOFe2O3, MgOFe2O3, EuO, and Y3Fe5O12.

The tunneling layer 22 may have a thickness thinner than a spin diffusion distance. The tunnel layer 22 may include a non-magnetic material. As an example, the tunnel layer 22 may include at least one selected from a group of Mg, Ti, Al, a compound of MgZn and MgB, and a nitride of Ti and V.

The pinned layer 23 may have a magnetization direction fixed by the anti-ferromagnetic layer 24. The pinned layer 23 may include a ferromagnetic material. For example, the pinned layer 23 may include at least one selected from a group of CoFeB, Fe, Co, Ni, Gd, Dy, CoFe, NiFe, MnAs, MnBi, MnSb, CrO2, MnOFe2O3, FeOFe2O3, NiOFe2O3, CuOFe2O3, MgOFe2O3, EuO, and Y3Fe5O12.

The anti-ferromagnetic layer 24 may include an anti-ferromagnetic material. For example, the anti-ferromagnetic layer 24 may include at least one selected from a group of PtMn, IrMn, MnO, MnS, MnTe, MnF2, FeCl2, FeO, CoCl2, CoO, NiCl2, NiO, and Cr.

Referring to FIG. 10, a pinned layer 33 may be formed of a synthetic anti-ferromagnetic (SAF) material. The pinned layer 33 may include a first ferromagnetic layer 33_1, a coupling layer 33_2, and a second ferromagnetic layer 33_3. Each of the first and second ferromagnetic layers may include at least one selected from a group of CoFeB, Fe, Co, Ni, Gd, Dy, CoFe, NiFe, MnAs, MnBi, MnSb, CrO2, MnOFe2O3, FeOFe2O3, NiOFe2O3, CuOFe2O3, MgOFe2O3, EuO, and Y3Fe5O12.

At this time, a magnetization direction of the first ferromagnetic layer 33_1 and a magnetization direction of the second ferromagnetic layer 33_3 may be different and fixed. The coupling layer 33_2 may include Ru.

FIG. 11 is a diagram illustrating a variable resistance element of an STT-MRAM according to still another embodiment of the inventive concept. In a variable resistance element in which magnetization directions are vertical to each other, a current direction and an easy axis may be substantially parallel with each other. Referring to FIG. 11, a variable resistance element VR may include a free layer 41, a pinned layer 43, and a tunnel layer 42.

A resistance value may become small when a magnetization direction of the free layer 41 and a magnetization direction of the pinned layer 43 are parallel, and may become large when a magnetization direction of the free layer 41 and a magnetization direction of the pinned layer 43 are anti-parallel. Data may therefore be stored according to a resistance value.

To implement a variable resistance element VR in which magnetization directions are vertical, it is desirable to form the free and pinned layers 41 and 43 using a material having a large magnetic anisotropy energy. The material with the large magnetic anisotropy energy may include an amorphous rare-earth element alloy, a multi-layer thin film such as (Co/Pt)n or (Fe/Pt)n, and a material having an L10 crystal structure.

For example, the free layer 41 may be an ordered alloy, and may include at least one of Fe, Co, Ni, Pa, or Pt. For example, the free layer 41 may include at least one of Fe—Pt alloy, Fe—Pd alloy, Co—Pd alloy, Co—Pt alloy, Fe—Ni—Pt alloy, Co—Fe—Pt alloy, or Co—Ni—Pt alloy. The alloys may be Fe5OPt50, Fe50Pd50, Co50Pd50, Co50Pt50, Fe30Ni20Pt50, Co30Fe20Pt50, or Co30Ni20Pt50.

The pinned layer 43 may be an ordered alloy, and may include at least one of Fe, Co, Ni, Pa, or Pt. For example, the pinned layer 43 may include at least one of Fe—Pt alloy, Fe—Pd alloy, Co—Pd alloy, Co—Pt alloy, Fe—Ni—Pt alloy, Co—Fe—Pt alloy, or Co—Ni—Pt alloy. The alloys may be Fe50Pt50, Fe50Pd50, Co50Pd50, Co50Pt50, Fe30Ni20Pt50, Co30Fe20Pt50, or Co30Ni20Pt50.

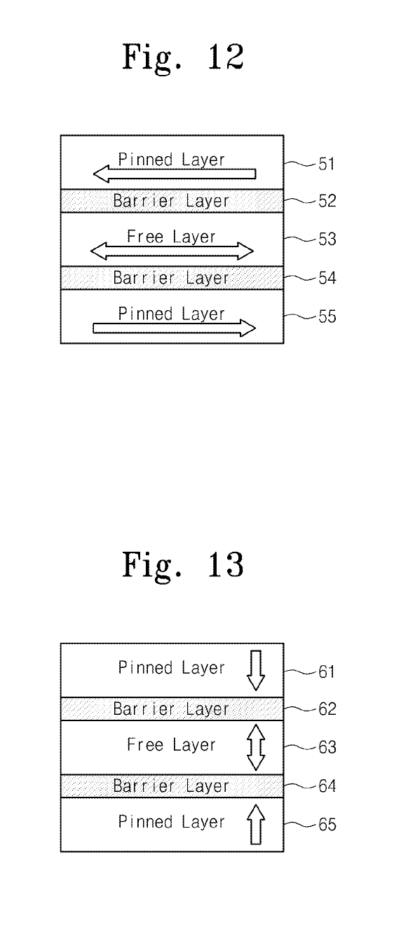

FIGS. 12 and 13 are diagrams illustrating variable resistance elements of an STT-MRAM according to still other embodiments of the inventive concept. A dual variable resistance element may have a structure in which a tunnel layer and a pinned layer are disposed at both ends on the basis of a free layer.

Referring to FIG. 12, the dual variable resistance element forming a horizontal magnetism may include a first pinned layer 51, a first tunnel layer 52, a free layer 53, a second tunnel layer 54, and a second pinned layer 55. Materials forming the respective layers may be equal or similar to those of layers 21, 22, and 23 in FIG. 9.

If a magnetization direction of the first pinned layer 51 and a magnetization direction of the second pinned layer 55 are fixed in an opposite direction, magnetic forces of the first and second pinned layers 51 and 55 may be offset. Thus, the dual variable resistance element may be written using a current that is less in amount than a typical variable resistance element.

Since the dual variable resistance element provides a larger resistance value by the second tunnel layer 54 at a read operation, it is possible to accurately obtain a data value.

Referring to FIG. 13, a dual variable resistance element forming vertical magnetism may include a first pinned layer 61, a first tunnel layer 62, a free layer 63, a second tunnel layer 64, and a second pinned layer 65. Materials forming the respective layers may be equal or similar to those of layers 41, 42, and 43 in FIG. 11.

If a magnetization direction of the first pinned layer 61 and a magnetization direction of the second pinned layer 65 are fixed in an opposite direction, magnetic forces of the first and second pinned layers 61 and 65 may be offset. Thus, the dual variable resistance element 60 may be written using a current that is less in amount than a typical variable resistance element.

As described with reference to FIGS. 3 to 13, a memory system 1200 according to an embodiment of the inventive concept may use a variable resistance element VR as a storage element. In the variable resistance element VR, the read mechanism may be the same as the write mechanism. For example, as described with reference to FIGS. 6 to 8, the read mechanism may be the same as the write mechanism except that the intensity of a read current is different that of a write current.

In a memory system in which a variable resistance element is used as a storage element, there may be a relatively high probability that data is corrupted by read disturbance. Further, since a memory system 1000 according to an embodiment of the inventive concept supports a comparison write operation, the probability that data is corrupted by read disturbance may become higher.

To prevent corruption of data, the memory system 1000 according to an embodiment of the inventive concept may selectively perform a comparison write operation or a rewrite operation based on an access number of a write requested block.

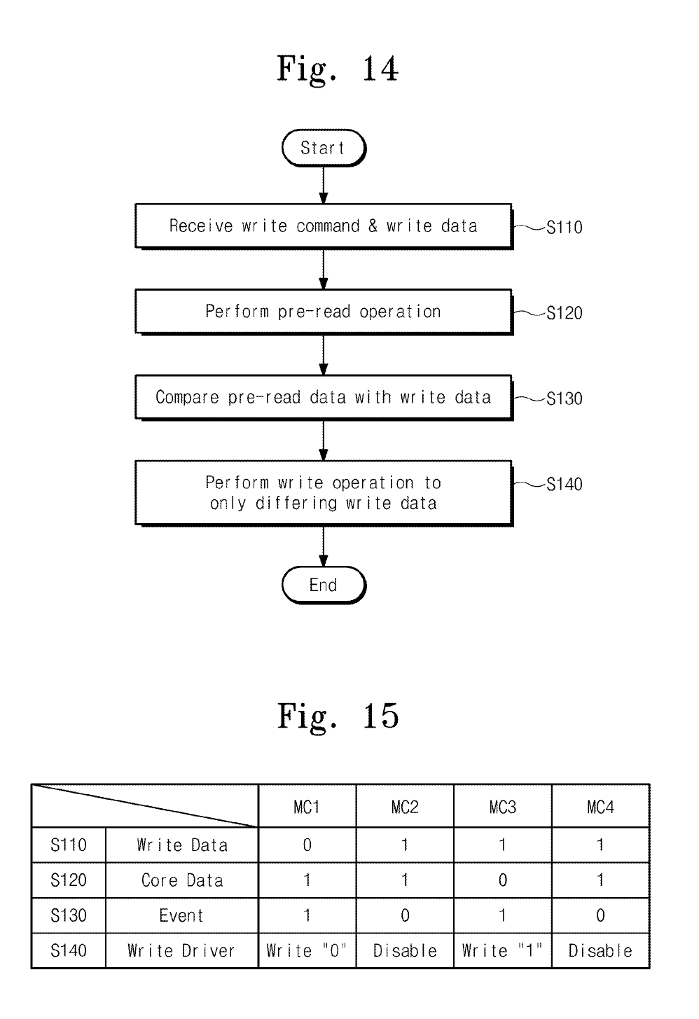

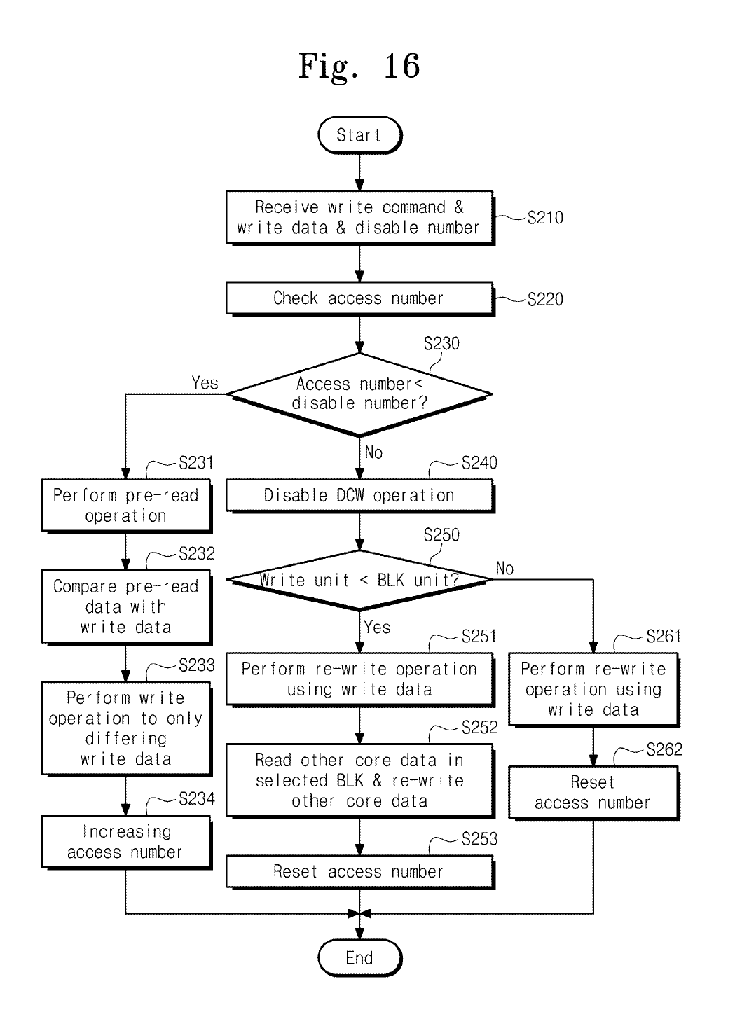

First, a comparison write operation according to an embodiment of the inventive concept will be described with reference to FIGS. 14 and 15. Afterwards, a write operation in which a comparison write operation and a rewrite operation are selectively performed will be described with reference to FIG. 16.

FIGS. 14 and 15 are diagrams for reference in describing a comparison write operation according to an embodiment of the inventive concept. For ease of description, it is assumed that a comparison write operation on first to fourth memory cells MC1 to MC4 is performed. Also, it is assumed that the first to fourth memory cells MC1 to MC4 share a first word line WL1 (refer to FIG. 3) and are respectively connected to first to fourth bit lines BL1 to BL4 (refer to FIG. 3).

In operation S110, a write command and write data may be received. For example, as illustrated in FIG. 15, it is assumed that write data bits are ‘0’, ‘1’, ‘1’, and ‘1’ and correspond to the first to fourth memory cells MC1 to MC4, respectively.

In operation S120, a pre-read operation may be performed. For example, data bits respectively stored at the first to fourth memory cells MC1 to MC4 may be read out. For example, as illustrated in FIG. 15, it is assumed that write data bits read out from the first to fourth memory cells MC1 to MC4 are ‘1’, ‘1’, ‘0’, and ‘1’, respectively. For ease of description, data read out from the first to fourth memory cells MC1 to MC4 may be referred to as core data.

In operation S130, the write data may be compared with the core data. If the write data coincides with (i.e., is the same as) the core data, an event ‘0’ may be generated. If the write data does not coincide with the core data, an event ‘1’ may be generated.

For example, as illustrated in FIG. 15, a write data bit and a core data bit corresponding to the second memory cell MC2 may coincide with each other. On the other hand, a write data bit and a core data bit corresponding to the first memory cell MC1 may not coincide with each other. Thus, an event ‘1’ may be generated with respect to the first memory cell MC1.

In operation S140, a data write operation may be performed with respect to memory cells storing code data bits different from write data bits. That is, a data write operation may not be performed with respect to a memory cell corresponding to an event ‘0’, while a data write operation may be performed with respect to a memory cell corresponding to an event ‘1’.

For example, as illustrated in FIG. 15, write requested data bits (i.e., write data bits) may be written at the first and third memory cells MC1 and MC3 each storing a code data bit different from a write data bit. On the other hand, write requested data bits (i.e., write data bits) may not be written at the second and fourth memory cells MC2 and MC4 each storing a code data bit coinciding with a write data bit.

As described with reference to FIGS. 14 and 15, the comparison write operation may include a pre-read operation. Thus, the probability that data is corrupted by read disturbance may be increased.

FIG. 16 is a flow chart illustrating a write operation according to an embodiment of the inventive concept. With a write operation of the inventive concept, a comparison write operation and a rewrite operation may be selectively performed according to an access number. The probability that data is corrupted by read disturbance may be lowered. Below, a write operation according to an embodiment of the inventive concept will be described with reference to accompanying drawings.

In operation S210, a storage device 1200 may receive a write command, write data, and a disable number. Also, the storage device 1200 may receive an address of a memory cell at which write requested data is to be stored and a block address indicating a block including the memory cell to be programmed.

In operation S220, control logic 1270 may check access information managed by a block counter 1260. For example, the control logic 1270 may check an access number of a block at which the write data is to be stored, through the block counter 1260. Herein, an access to a block may mean a comparison write operation or a read operation on the block, and an access number of the block may indicate a sum of the number of comparison write operations on the block and the number of read operations on the block.

In operation S230, the control logic 1270 may compare an access number (i.e., a block counting number) of the block with the disable number to determine whether the access number is less than the disable number.

If the access number is less than the disable number, operations S231 to S234 may be performed. That is, if the access number is less than the disable number, the control logic 1270 may control a write driver 1220, a sense amplifier 1230, and a data comparison write unit 1240 to perform a comparison write operation.

In operation S231, a pre-read operation may be performed. In operation S232, the write data may be compared with core data. In operation S233, write data different from the core data may be written at memory cells. These operations S231 to S233 may be the same as those described with reference to FIGS. 14 and 15, and a more detailed description thereof is thus omitted here. Afterwards, in operation S234, the block counter 1260 may increase an access number of the block by ‘1’.

On the other hand, in operation S230, if the access number is equal to or more than the disable number, the control logic 1270 may control the storage device 1200 to perform a rewrite operation.

In operation S240, the control logic 1270 may control the comparison write unit 1240 such that the comparison write operation is disabled or not performed. Afterwards, in operation S250, the control logic 1270 may compare a write unit with a block unit.

That the write unit is less than the block unit may mean that a block corresponding to the write data includes memory cells besides a memory cell corresponding to the write data. For example, as described with reference to FIG. 15, it is assumed that write data bits correspond to first to fourth memory cells MC 1 to MC4, respectively. If the write unit is less than the block unit, a block may include memory cells besides the first to fourth memory cells MC1 to MC4. In this case, the control logic 1270 may control the storage device 1200 such that a rewrite operation is performed with respect to all memory cells of a block corresponding to the write data.

In operation S251, the control logic 1270 may control the storage device 1200 such that the write data is written at corresponding memory cells. In this case, the control logic 1270 may control the storage device 1200 such that the write data is written at corresponding memory cells without a pre-read operation.

In operation S252, the control logic 1270 may perform a read operation on a block corresponding to the write data and an operation in which the read data is again written at the block. In this case, for example, the control logic 1270 may perform read and write operations (operation S251) except for memory cells at which the write data is written. As another example, the control logic 1270 may perform read and write operations (operation S251) including a block at which the write data is written.

In operation S253, the control logic 1270 may reset an access number of a block, corresponding to the write data, from among access information managed by the block counter 1260.

If the write unit is equal to the block unit, in operation S261, the control logic 1270 may control the storage device 1200 such that the write data is written at corresponding memory cells. Afterwards, in operation S262, the control logic 1270 may reset an access number of a block, corresponding to the write data, from among access information managed by the block counter 1260.

As described in FIG. 16, the storage device according to an embodiment of the inventive concept may selectively perform a comparison write operation and a rewrite operation according to an access number of a write requested block. Thus, it is possible to prevent data from being corrupted by read disturbance.

In example embodiments, the disable number may be variously set by a designer. For example, the disable number may be variously adjusted according to physical characteristics of memory cells of a memory cell array 1210 (refer to FIG. 2). The disable number of a memory cell array formed of memory cells having the high durability may be set to be larger than the disable number of a memory cell array formed of memory cells having the low durability.

Also, the disable number may be set to be changed according to the number of read operations. For example, it is assumed that a disable number of a block is set to 10. Afterwards, it is assumed that a comparison write operation or a read operation is iteratively performed with respect to the block.

With this assumption, memory cells of the block may be deteriorated by iterative execution of the comparison write operation or the read operation. This may mean that the memory cells of the block are easily affected by the read disturbance. In this case, for example, a memory system according to an embodiment of the inventive concept may prevent data from being corrupted by the read disturbance by changing the disable number from 10 to 2.

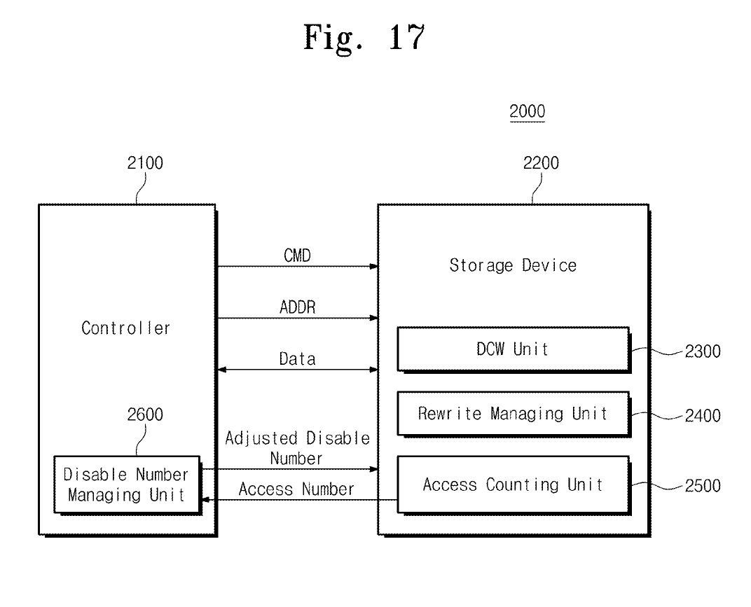

Below, embodiments of the inventive concept in which a disable number is adjusted will be more fully described with reference to FIGS. 17 to 22.

FIG. 17 is a block diagram schematically illustrating a memory system according to another embodiment of the inventive concept. A memory system 2000 in FIG. 17 may be the same or substantially the same as a memory system 1000 in FIG. 1, except for the following difference.

The memory system 2000 may be configured to adjust a disable number according to an access number. Compared with the memory system 1000, the memory system 2000 may further include an access counting unit 2500 and a disable number managing unit 2600.

The access counting unit 2500 may count an access number by which a storage device 2200 is accessed by a controller 2100. For ease of description, below, it is assumed that the access number means a sum of the number of comparison write operations and the number of read operations. However, the inventive concept is not limited thereto. For example, the access number may mean the number of comparison write operations (i.e., the number of pre-read operations) or the number of read operations.

The access counting unit 2500 may count an access number by which the storage device 2200 is accessed by the controller 2100, and may send the counted access number to the disable number managing unit 2600. The disable number managing unit 2600 may provide the storage device 2200 with a disable number adjusted according to a total access number.

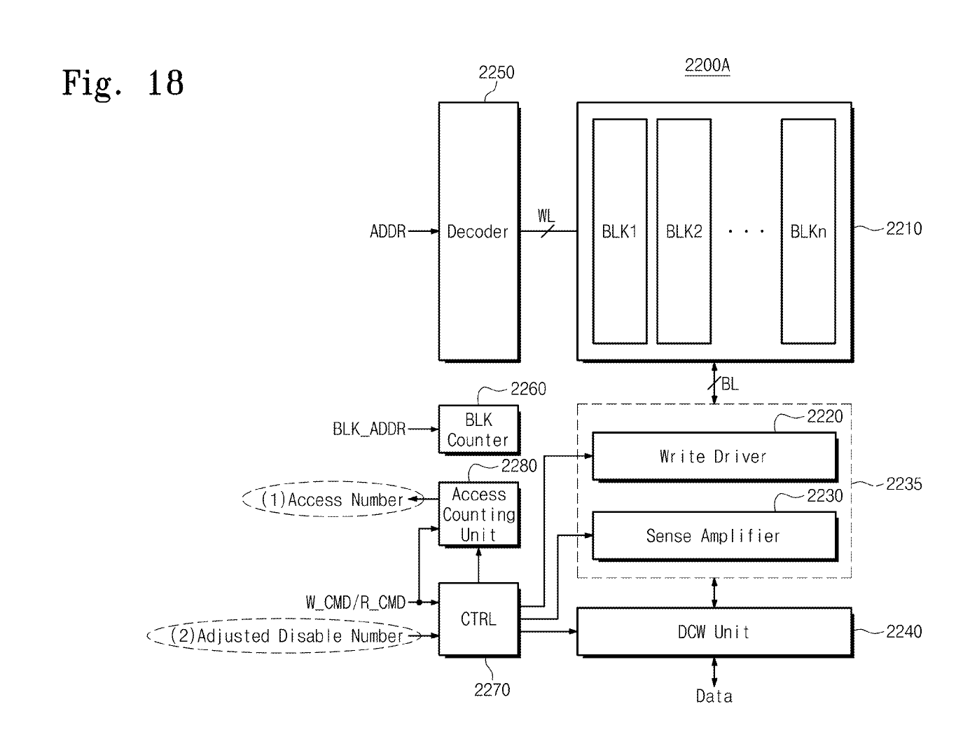

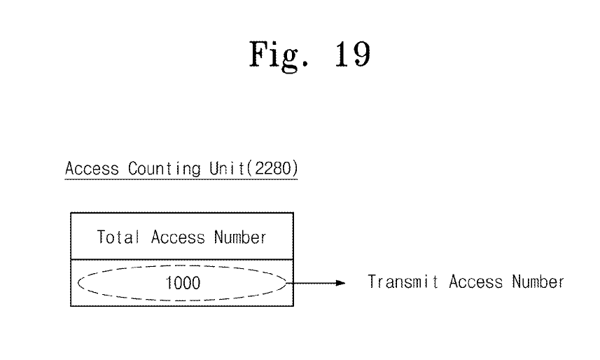

For example, the access counting unit 2500 may count a total access number of the storage device 2000 regardless of a block accessed, and may provide the counted total access number to the disable number managing unit 2600. In this case, the disable number managing unit 2600 may adjust a disable number according to the total access number, and may provide the adjusted disable number to the storage device 2200. This will be more fully described with reference to FIGS. 18 and 19.

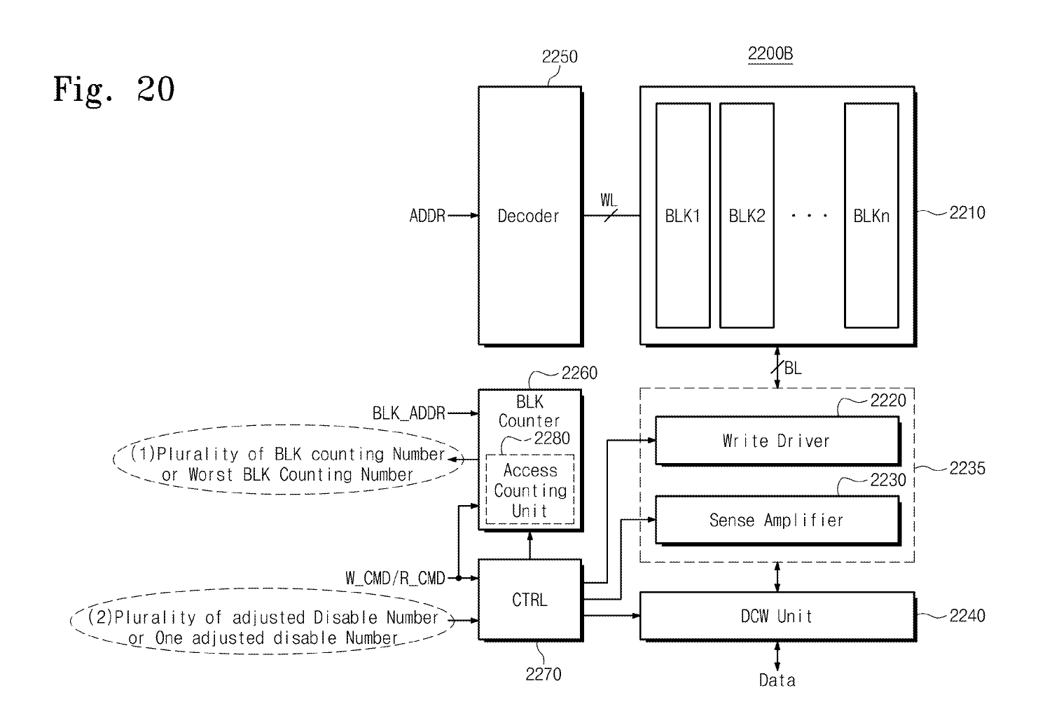

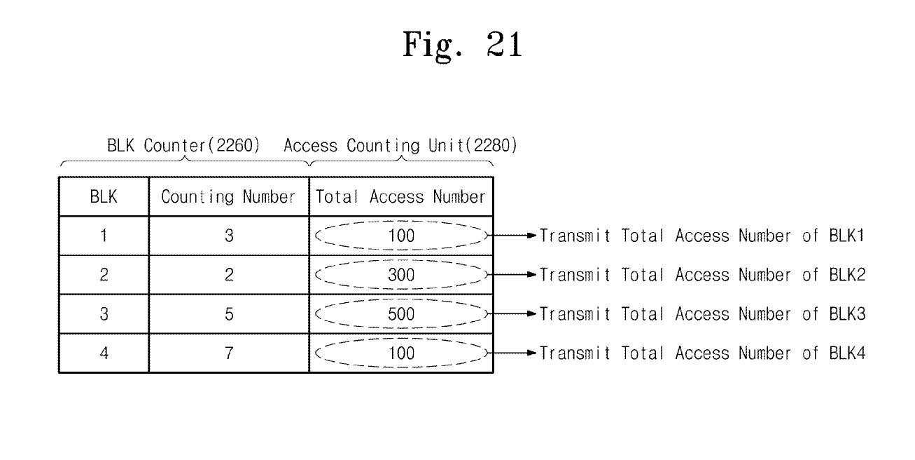

In other example embodiments, the access counting unit 2500 may count an access number of each block to provide it to the disable number managing unit 2600. In this case, the disable number managing unit 2600 may adjust disable numbers of blocks to provide them to the storage device 2200. This will be more fully described with reference to FIGS. 20 and 21.

In still other example embodiments, the access counting unit 2500 may count access numbers of blocks, and may provide an access number corresponding to the worst block of the blocks to the disable number managing unit 2600. In this case, the disable number managing unit 2600 may adjust a disable number to provide it to the storage device 2200. This will be more fully described with reference to FIGS. 20 and 21.

FIG. 18 is a block diagram schematically illustrating a storage device shown in FIG. 17 according to an embodiment of the inventive concept. FIG. 19 is a diagram illustrating an operation of a storage device shown in FIG. 18. A storage device 2200A in FIG. 18 may be the same as a storage device 1200 shown in FIG. 2 except for the following difference.

Compared with the storage device 1200 in shown FIG. 2, the storage device 2200A may further comprise an access counting unit 2280. The access counting unit 2280 may count an access number by which the storage device 2200A is accessed by a controller 2100 (refer to FIG. 17), and may provide a count result to a disable number managing unit 2600 (refer to FIG. 17). The disable number managing unit 2600 may adjust a disable number according to an input access number to provide the adjusted disable number to the storage device 2200A.

Referring to FIG. 19, for example, the access counting unit 2280 may count a total access number by which the controller 2100 accesses the storage device 2200A. If the total access number reaches a predetermined number, the access counting unit 2280 may provide information to the controller 2100.

As illustrated in FIG. 19, if the total access number reaches ‘1000’, the access counting unit 2280 may provide information to the disable number managing unit 2600 of the controller 2100. In this case, the disable number managing unit 2600 may adjust a disable number to provide the adjusted disable number to the storage device 2200A. For example, the disable number managing unit 2600 may change the disable number from ‘10’ to ‘2’.

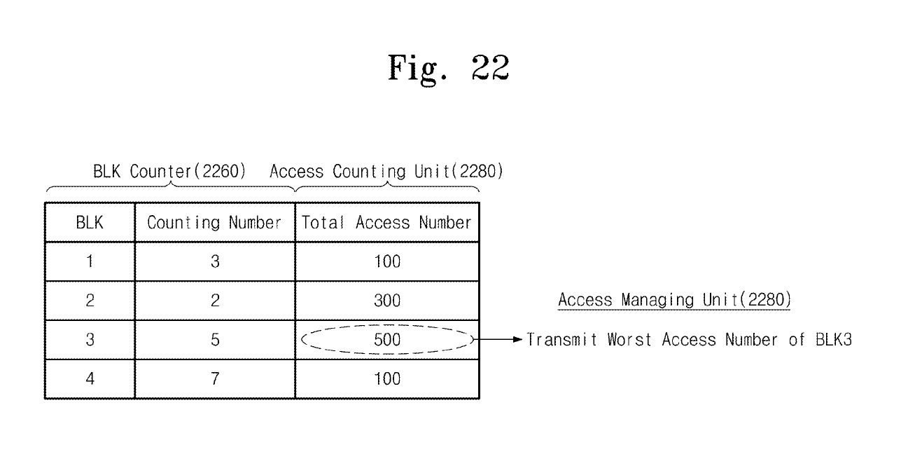

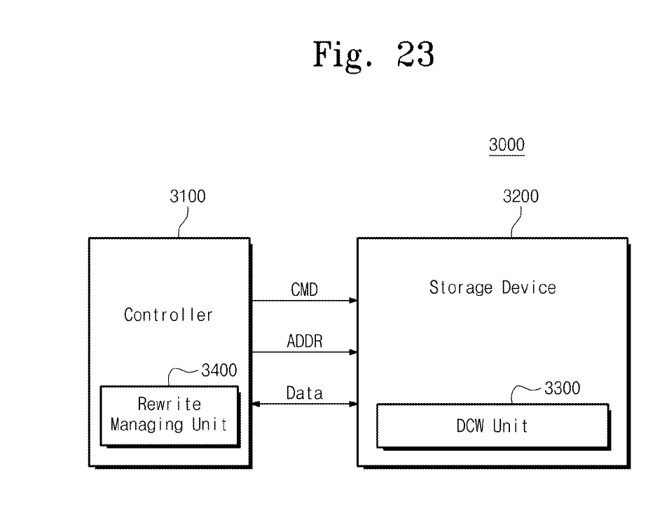

FIG. 20 is a block diagram schematically illustrating a storage device in shown FIG. 17 according to another embodiment of the inventive concept. FIGS. 21 and 22 are diagrams illustrating an operation of a storage device shown in FIG. 20. A storage device 2200B shown in FIG. 20 may be the same as a storage device 1200 shown in FIG. 2 except for the following difference.

Compared with the storage device 1200 shown in FIG. 2, the storage device 2200B may further comprise an access counting unit 2280. The access counting unit 2280 may be implemented by a module together with a block counter 2260. The access counting unit 2280 may count an access number of each block, and may provide a count result to a disable number managing unit 2600 of a controller 2100 (refer to FIG. 17).

Referring to FIG. 21, the access counting unit 2280 may count a total access number on each block. If an access number of each block reaches a reference number, the access counting unit 2280 may provide information to the disable number managing unit 2600 of the controller 2100.

For ease of description, it is assumed that reference numbers of first to fourth blocks BLK1 to BLK4 are set to ‘100’, ‘300’, ‘500’, and ‘100’, respectively. A reference number of each block may be variously set according to a physical characteristic of each block.

As illustrated in FIG. 21, if a total access number of each block reaches a reference number, the access counting unit 2280 may provide information to the disable number managing unit 2600 of the controller 2100. The disable number managing unit 2600 may adjust a disable number of each block to provide it to the storage device 2200B.

As another example, referring to FIG. 22, reference numbers of all blocks may be set to be equal to each other. In this case, the access counting unit 2280 may count a total access number of each block. If a block (i.e., the worst block), having an access number reaching a reference number, from among blocks exists, the access counting unit 2280 may provide information to the disable number managing unit 2600 of the controller 2100. The disable number managing unit 2600 may adjust disable numbers of all blocks to provide the adjusted disable numbers to the storage device 2200B.

As described with reference to FIGS. 17 to 22, a storage device according to an embodiment of the inventive concept may adjust a disable number according to an access number of the storage device or each block. The storage device may selectively perform a comparison write operation and a rewrite operation based on a comparison result of an access number of a write requested block and an adjusted disable number. Thus, it is possible to prevent data from being corrupted by read disturbance.

FIG. 23 is a block diagram schematically illustrating a memory system according to another embodiment of the inventive concept. A memory system 3000 shown in FIG. 23 may be the same as a memory system 1000 shown in FIG. 1 except for the following difference.

Referring to FIG. 23, the memory system 3000 may include a controller 3100 and a storage device 3200. The controller 3100 may include a rewrite managing unit 3400, and the storage device 3200 may include a data comparison write unit 3300.

Unlike the memory system 1000 shown in FIG. 1, the rewrite managing unit 3400 of the memory system 3000 may be placed in the controller 3100. That is, the controller 3100 may be configured to include the rewrite managing unit 3400.

In the event that a write operation is requested by a host, the rewrite managing unit 3400 may check an access number by which the storage device 3200 is accessed by the controller 3100. Afterwards, the rewrite managing unit 3400 may select a comparison write operation or a rewrite operation according to an access number such that the storage device 3200 performs the selected operation. It is possible to prevent data from being corrupted by read disturbance by performing the comparison write operation and the rewrite operation selectively.

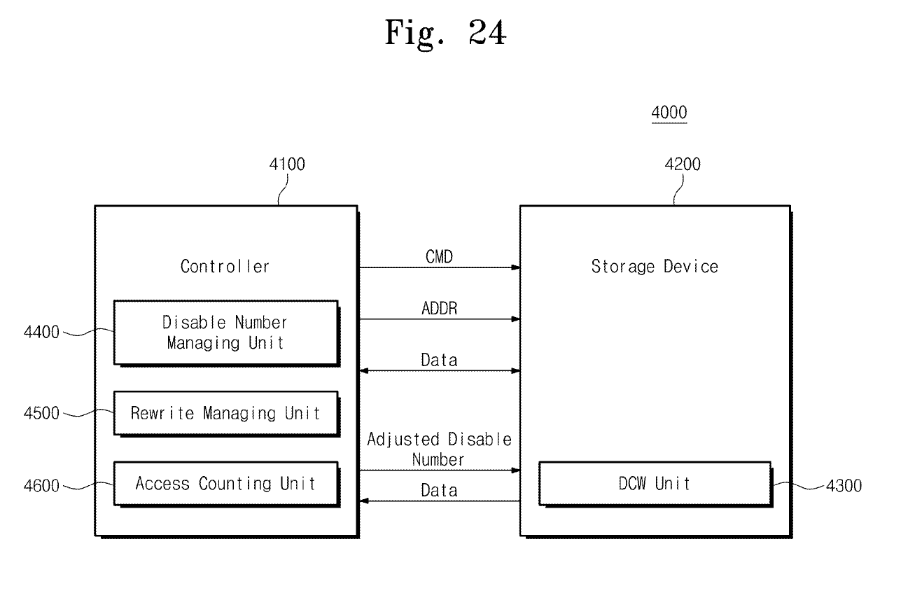

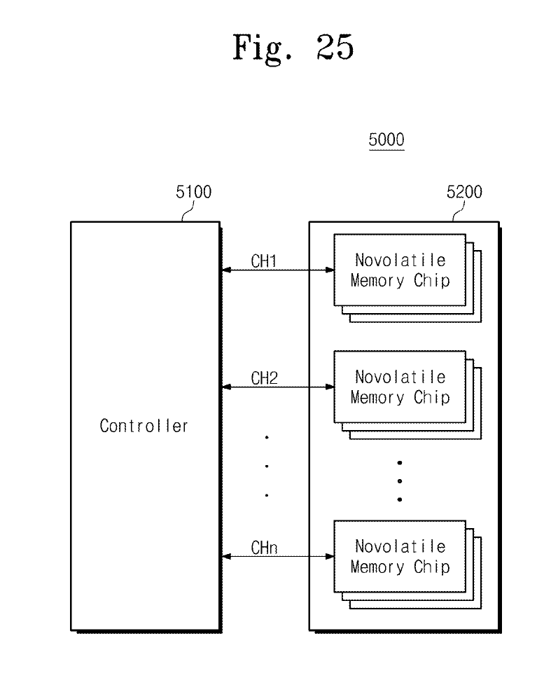

FIG. 24 is a block diagram schematically illustrating a memory system according to still another embodiment of the inventive concept. A memory system 4000 shown in FIG. 24 may be the same as memory systems 2000 and 3000 shown in FIGS. 17 and 23 except for the following difference.

Referring to FIG. 24, the memory system 4000 may include a controller 4100 and a storage device 4200. The controller 4100 may include a disable number managing unit 4400, a rewrite managing unit 4500, and an access counting unit 4600, and the storage device 4200 may include a data comparison write unit 4300. The controller 4100 may be configured to include the disable number managing unit 4400, the rewrite managing unit 4500, and the access counting unit 4600.

For example, the access counting unit 4600 may count a total access number of the storage device 4200 or a total access number of each block. The access counting unit 4600 may provide counting information to the disable number managing unit 4400 and the rewrite managing unit 4500.

The disable number managing unit 4400 may adjust a disable number to provide the adjusted disable number to the rewrite managing unit 4500. The rewrite managing unit 4500 may select a comparison write operation or a rewrite operation according to the adjusted disable number or the counting information, and may provide the storage device 4200 with a command associated with the selected operation.

Thus, it is possible to prevent data from being corrupted by read disturbance by performing the comparison write operation and the rewrite operation selectively.

FIG. 25 is a block diagram schematically illustrating a memory system according to still another embodiment of the inventive concept. It was assumed that a nonvolatile memory device described with reference to FIGS. 1 to 24 is formed of a nonvolatile memory chip. However, the inventive concept is not limited thereto. For example, the inventive concept may be applied to a case in which a plurality of nonvolatile memory chips is used.

Referring to FIG. 25, a memory system 5000 may include a controller 5100 and a storage device 5200. The storage device 5200 may include a plurality of nonvolatile memory chips, which are divided into a plurality of groups.

Nonvolatile memory chips in each group may be configured to communicate with the controller 5100 through one common channel. In FIG. 25, there is illustrated an example in which a plurality of nonvolatile memory chips communicates with the controller 5100 through a plurality of channels CH1 to CHn. Each nonvolatile memory chip may be configured the same or substantially the same as storage devices described with reference to FIGS. 1 to 24. The controller 5100 may be configured the same or substantially the same as a controller described with reference to FIGS. 1 to 14.

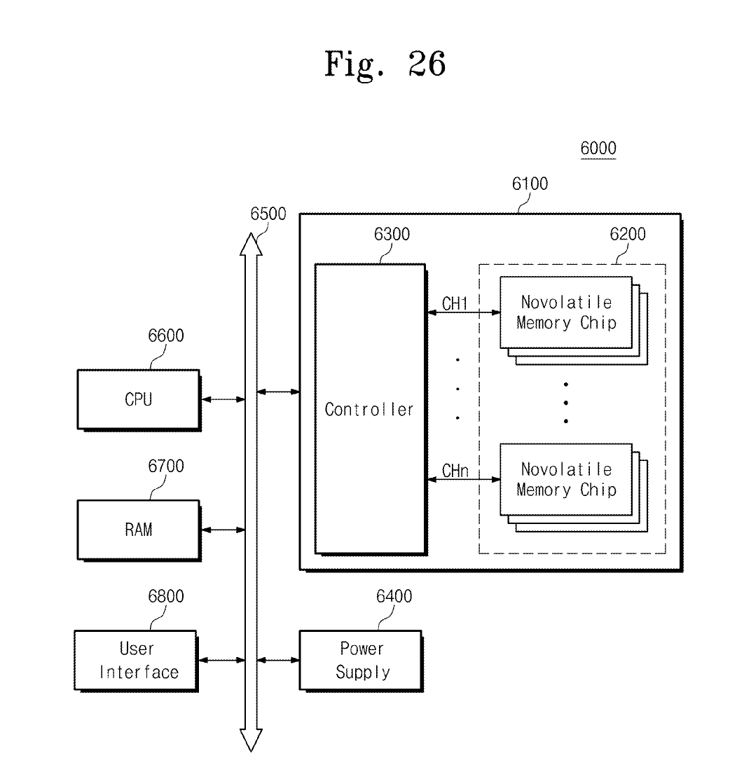

FIG. 26 is a block diagram schematically illustrating a computing system including a memory system according to an embodiment of the inventive concept. Referring to FIG. 26, a computing system 6000 may include a CPU 6600, a RAM 6700, a user interface 6800, a power supply 6400, and a memory system 6100.

The memory system 6100 may be electrically connected with the components 6400, 6600, 6700, and 6800 through a system bus 6500. Data provided through the user interface 8800 or processed by the CPU 6600 may be stored at the memory system 6100. The memory system 6100 may include a controller 6200 and a nonvolatile memory device 6300.

In example embodiments, the computing system 6000 may be configured to include memory systems 1000, 2000, 3000, 4000, and 5000 described with reference to FIGS. 1 to 25.

While the inventive concept has been described with reference to exemplary embodiments, it will be apparent to those skilled in the art that various changes and modifications may be made without departing from the spirit and scope of the present invention. Therefore, it should be understood that the above embodiments are not limiting, but illustrative.

What is claimed is:

1. A nonvolatile memory device comprising:
a memory cell array including a plurality of memory cells;
a data comparison write unit connected with the memory cell array and configured to support a comparison write operation; and
control logic configured to selectively perform the comparison write operation based on a comparison between an access number of the memory cell array and a reference number.

2. The nonvolatile memory device of claim 1, wherein when the access number is less than the reference number, the control logic performs the comparison write operation.

3. The nonvolatile memory device of claim 2, wherein during the comparison write operation, the data comparison write unit reads data stored in an addressed memory cell of write data, and compares the read data with the write data.

4. The nonvolatile memory device of claim 3, wherein during the comparison write operation, the write data is written in the addressed memory cell when the write data does not coincide with the read data, and the write data is not written in the addressed memory cell when the write data coincides with the read data.

5. The nonvolatile memory device of claim 1, wherein when the access number is equal to or more than the reference number, the control logic performs a rewrite operation and does not perform the comparison write operation.

6. The nonvolatile memory device of claim 5, wherein during the rewrite operation, the control logic overwrites an addressed memory cell with write data.

7. The nonvolatile memory device of claim 6, wherein the control logic compares a write unit of the memory cell array with an access unit of the memory cell array, reads data stored in predetermined memory cells among the plurality of memory cells when the write unit is less than the access unit, and overwrites the read data in the predetermined memory cells.

8. The nonvolatile memory device of claim 7, wherein the predetermined memory cells correspond to a same memory block as the write data.

9. The nonvolatile memory device of claim 1, further comprising:
an access counting unit configured to count a access number of each of a plurality of blocks of the memory cell array.

10. The nonvolatile memory device of claim 9, wherein the reference number differs according to the blocks of the memory cell array.

11. The nonvolatile memory device of claim 1, wherein the plurality of memory cells is formed of variable resistance elements.

12. A nonvolatile memory device comprising:
a memory cell array including a plurality of memory blocks, each of the memory blocks including a plurality of memory cells;
a data comparison write unit connected with the memory cell array and configured to support a comparison write operation; and
control logic configured to, in response to a write command and write data for a memory block among the plurality of memory blocks, selectively execute either the comparison write operation or a rewrite operation based on a comparison between an access number of the memory block and a reference number of the block.

13. The nonvolatile memory device of claim 12, wherein the comparison write operation is executed when the access number is less than the reference number, and the rewrite operation is executed when the access number is greater than or equal to the reference number.

14. The nonvolatile memory device of claim 12, wherein the access number is indicative of a number of read accesses of the memory block, and wherein the nonvolatile memory device further comprises a counter for counting the number of read accesses of each of the plurality of memory blocks.

15. The nonvolatile memory device of claim 12, wherein at least two of the memory blocks have a different reference number.

16. The nonvolatile memory device of claim 12, wherein the memory cell array includes at least one of magnetoresistive random access memory (MRAM), spin transfer torque magnetoresistive random access memory (STT-MRAM), phase change random access memory (PRAM), and resistive random access memory (RRAM).

17. A write method of a nonvolatile memory device comprising:
receiving a write command and write data;
checking access information of a memory block corresponding to the write data in response to the write command; and
performing either one of a comparison write operation and a rewrite operation based on the access information.

18. The write method of claim 17, wherein the comparison write operation is performed when an access number of an addressed memory block of the write data is less than a reference number, and the rewrite operation is performed when the access number of the addressed memory block of the write data is equal to or more than the reference number.

19. The write method of claim 18, wherein the comparison write operation comprises:
reading data stored in the addressed memory block;
comparing the read data with the write data; and
overwriting the write data in the memory block when the read data does not coincide with the write data.

20. The write method of claim 17, wherein the rewrite operation comprises:
writing the write data in an addressed memory block of the write data; and
resetting an access number of the addressed memory block.
